(19) United States
(12) Patent Application Publication
(10) Pub. No.: US 2025/0149474 A1
(43) Pub. Date: May 8, 2025

(54) Selective Dielectric Capping for Hybrid Bonding

(71) Applicants: Applied Materials, Inc., Santa Clara, CA (US); Nanyang Technological University, Singapore (SG)

(72) Inventors: Prayudi LIANTO, Singapore (SG); Chuan Seng TAN, Singapore (SG)

(21) Appl. No.: 18/809,472

(22) Filed: Aug. 20, 2024

Related U.S. Application Data
(60) Provisional application No. 63/547,222, filed on Nov. 3, 2023.

(51) Int. Cl. H01L 23/00; H01L 21/02; H01L 21/67; H01L 21/762

(52) U.S. Cl. CPC H01L 24/03; H01L 21/0201; H01L 21/02178; H01L 21/02181; H01L 21/67057; H01L 21/76251; H01L 24/80; H01L 24/05; H01L 24/08; H01L 2224/03009; H01L 2224/033; H01L 2224/03522; H01L 2224/05073; H01L 2224/05541; H01L 2224/05624; H01L 2224/05639; H01L 2224/05644; H01L 2224/05647; H01L 2224/05655; H01L 2224/05657; H01L 2224/05664; H01L 2224/05666; H01L 2224/05669; H01L 2224/05687; H01L 2224/0801; H01L 2224/08059; H01L 2224/08145; H01L 2224/08225; H01L 2224/80097; H01L 2224/8083; H01L 2224/80895; H01L 2224/80896; H01L 2224/80907; H01L 2924/351

(57) ABSTRACT

A method for increasing dielectric bonding strength during wafer-level processing is incorporated into a hybrid bonding process. A method may include immersing a substrate into a chemical bath at atmospheric conditions where the chemical bath forms a self-assembled monolayer on metal surfaces of the substrate and selectively depositing a high-k dielectric material to form a dielectric cap on dielectric surfaces of the substrate absent of the self-assembled monolayer.

### CROSS-REFERENCE TO RELATED APPLICATIONS

This application claims the benefit of the U.S. provisional patent application Ser. No. 63/547,222, filed Nov. 3, 2023, which is herein incorporated by reference in its entirety.

### FIELD

Embodiments of the present principles generally relate to semiconductor processing of semiconductor substrates.

### BACKGROUND

Dies are attached to substrates using a bonding process during wafer-level processing. When the dies have surface features comprising metal and dielectric materials that are to connect with other metal and dielectric materials on the substrate, the process is known as hybrid bonding due to the bonding of more than one type of material. To increase the bond or attraction of the dielectric materials between the dies and substrates, the dies and substrates are put through complex preparation processes prior to the bonding process. However, the inventors have observed that a substantial reduction in dielectric bonding area due to ever increasing densities of interconnects is causing bonding defects. The reduced dielectric bonding area causes a diminished overall dielectric bonding strength of the dies, leading to low bonding yields.

Accordingly, the inventors have provided methods for improving dielectric bonding strength for hybrid bonding.

### SUMMARY

Methods for improving dielectric bonding strength for hybrid bonding are provided herein.

In some embodiments, a method for increasing dielectric bonding strength during wafer-level processing may comprise immersing a substrate into a chemical bath where the chemical bath forms a self-assembled monolayer on at least one metal surface of the substrate and selectively depositing a dielectric material to form a dielectric cap on at least one dielectric surface of the substrate absent of the self-assembled monolayer.

In some embodiments, the method may further include immersing a substrate into a chemical bath occurs at atmospheric pressure and ambient temperature; removing the self-assembled monolayer from the substrate, bonding the dielectric material of the substrate to another substrate with surfaces covered by the dielectric material by contacting substrates together, and annealing substrates to bond metal surfaces together; removing the self-assembled monolayer using a plasma-based process for approximately 10 seconds to approximately 60 seconds, a substrate that is a die; annealing that occurs at a temperature of approximately 150 degrees Celsius; a chemical bath that includes an alkanethiol; an alkanethiol that has a linear structure or a benzene ring structure; a dielectric material that is a high-k dielectric material; a high-k dielectric material that is aluminum oxide or hafnium oxide; a substrate that is immersed in the chemical bath for approximately 10 minutes to approximately 30 minutes; a metal surface that is copper, silver, gold, palladium, platinum, cobalt, titanium, nickel, or combinations thereof; and/or a thickness of the dielectric material that is greater than zero nm to approximately 10 nm.

In some embodiments, a method for increasing dielectric bonding strength during wafer-level processing may comprise immersing a substrate into a chemical bath where the chemical bath forms a self-assembled monolayer on at least one metal surface of the substrate and where immersing the substrate into the chemical bath occurs at atmospheric pressure and ambient temperature and selectively depositing a high-k dielectric material to form a dielectric cap on at least one dielectric surface of the substrate absent of the self-assembled monolayer where a thickness of the high-k dielectric material is greater than zero nm to approximately 10 nm.

In some embodiments, the method may further include a substrate that is immersed in the chemical bath for approximately 10 minutes to approximately 30 minutes; removing the self-assembled monolayer from the substrate, bonding the high-k dielectric material of the substrate to another substrate with surfaces covered by the high-k dielectric material by contacting substrates together, and annealing substrates to bond metal surfaces together; removing the self-assembled monolayer using a plasma-based process for approximately 10 seconds to approximately 60 seconds; a chemical bath includes an alkanethiol with a linear structure or a benzene ring structure; and/or a high-k dielectric material that is aluminum oxide or hafnium oxide.

In some embodiments a non-transitory, computer readable medium having instructions stored thereon that, when executed, cause a method for increasing dielectric bonding strength during wafer-level processing to be performed, the method may comprise immersing a substrate into a chemical bath where the chemical bath forms a self-assembled monolayer on at least one metal surface of the substrate and where immersing the substrate into the chemical bath occurs at atmospheric pressure and ambient temperature and selectively depositing a high-k dielectric material to form a dielectric cap on at least one dielectric surface of the substrate absent of the self-assembled monolayer where a thickness of the high-k dielectric material.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is a method for increasing dielectric bonding strength during wafer-level processing in accordance with some embodiments of the present principles.

FIG. 2 depicts cross-sectional views of a substrate undergoing a process to increase dielectric bonding strength in accordance with some embodiments of the present principles.

FIG. 3 depicts cross-sectional views of substrates undergoing a hybrid bonding process in accordance with some embodiments of the present principles.

FIG. 4 is a top-down view of a hybrid bonding tool in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods provide improved bonding dielectric bonding strength for hybrid bonding processes. A dielectric capping layer is selectively formed on a substrate that enhances the bonding strength between, for example, a die and a substrate during wafer-level processing. The increased dielectric bonding strength enables higher copper density for increased input/output connections and ensures higher interconnect reliability. The selective dielectric capping layer is formed without changing the overall copper damascene process integration, easily integrating into existing hybrid bonding process flows.

The present techniques use a self-assembled monolayer (SAM) to selectively deposit a dielectric onto a substrate with, for example, a completed copper or other metal damascene structure. The SAM material used may be, but is not limited to, an alkanethiol with a linear structure or a benzene ring structure and the like that forms on metal surfaces and provides a hydrophobic layer. The SAM may have a thickness of a few angstroms to a few nanometers and can be coated on the substrate using an immersion method in ambient conditions. The selectively deposited dielectric material may include high-k dielectric materials such as, but not limited to, aluminum oxide, titanium oxide, or hafnium oxide and the like with a thickness of a few angstroms to a few nanometers. The selective dielectric process may include, but not limited to, atomic layer deposition (ALD) processes and the like.

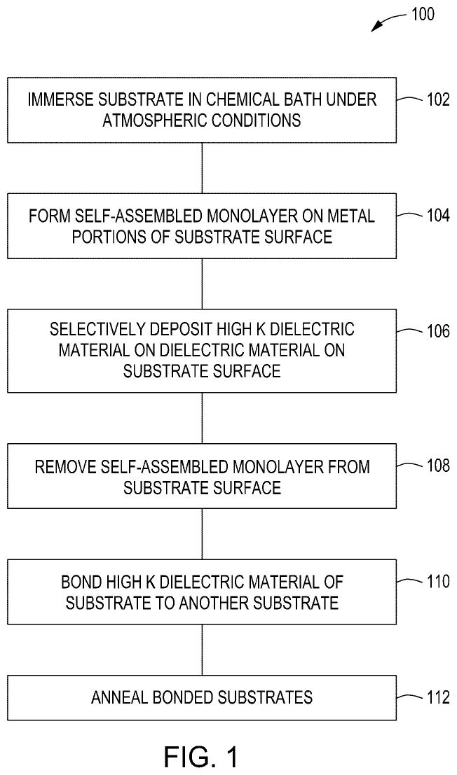

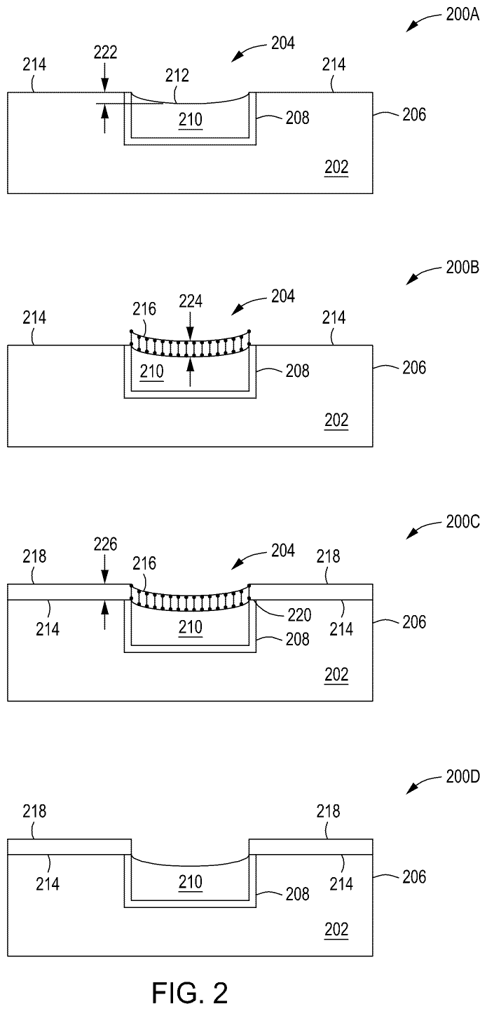

FIG. 1 is a method 100 for increasing dielectric bonding strength during wafer-level processing. The method 100 can be easily integrated into hybrid bonding integration flows. As used herein a ‘substrate’ may include a die, a substrate of multiple dies, and/or a bonded substrate on which one or more dies may be bonded onto a surface of the substrate. During wafer-level processing, a substrate may be formed that includes multiple dies that are then separated and bonded to another substrate to form other semiconductor structures. The present techniques may be applied, for example, to a substrate with a single die or structure, to a substrate of multiple dies, and/or to one or more singulated dies. For the sake of brevity, a substrate 202 with a single structure 204 as depicted in a view 200A of FIG. 2 is used as an example. The substrate 202 may be a dielectric material 206 such as, but not limited to, silicon-based materials, for example, silicon dioxide and the like.

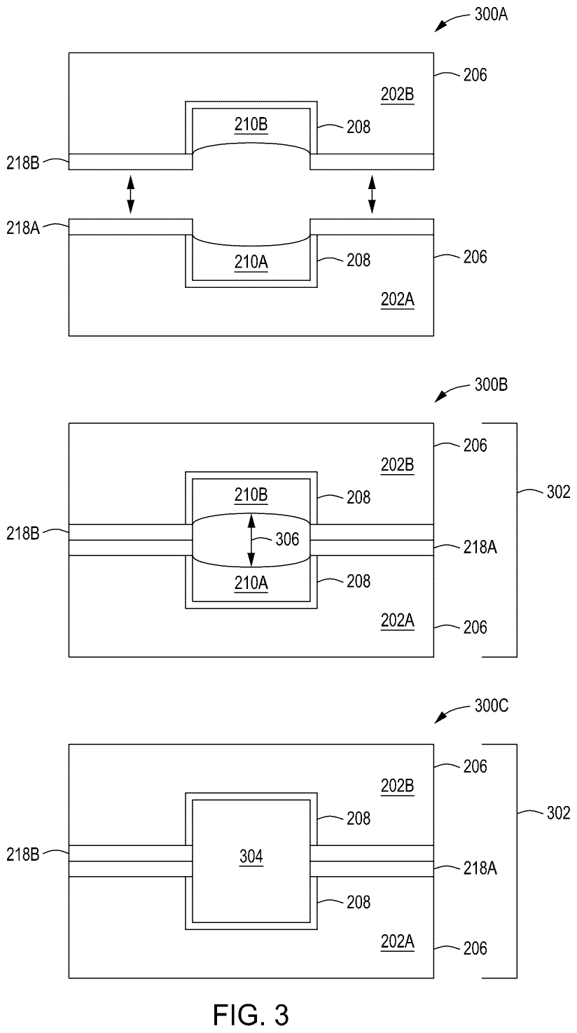

A barrier/liner layer 208 may be formed prior to the deposition of a metal material 210. The metal material 210 may be, but is not limited to, copper and other conductive interconnect materials such as Ag, Au, Pd, Pt, Co, Ti, Ni, or combinations thereof, such as, but not limited to, Cu/Ag, Cu/Pd, and the like. During processing of the substrate 202, chemical mechanical polishing (CMP) may be performed on the top surface 214 of the substrate 202 which tends to cause dishing 212 of the metal material 210 due to the softness of the metal material 210 compared to the dielectric material 206. In hybrid bonding processes, the dishing 212 of the metal material 210 aids in allowing the dielectric material 206 to come into contact first and bond firmly before the metal material 210. The dishing 212, as depicted, has been exaggerated to better show the dishing curve. The dishing 212, in some embodiments, is approximately 2.5 nm or less in height 222. A subsequent annealing process of the bonded substrates allows the metal material 210 to diffuse and form into an interconnect between the bonded substrates (e.g., see view 300C of FIG. 3).

In block 102, the substrate 202 is immersed into a chemical bath under atmospheric conditions (ambient pressure, room temperature, etc.). In some embodiments, the chemical bath includes an alkanethiol with a linear chain structure (e.g., SH—(CH₂)ₙ—CH₃) or a benzene ring structure along with alcohol and the like. The linear chain alkanethiol may include C6, C8, or C12 alkanethiols. The SH end of the alkanethiol molecule has a strong affinity for some types of metals like copper and others. At the other end of the linear chain, the CH₃ end of the alkanethiol is hydrophobic (repels water). During immersion, the alkanethiol molecule will attach the SH end to the metal surface and the CH₃ end will extend vertically upwards. A dense concentration of the alkanethiol molecules provides a passivation layer for the surface of the metal at the SH end along with a hydrophobic layer at the CH₃ end. In some embodiments, the immersion process may have a duration of approximately 10 minutes to approximately 30 minutes.

In block 104, the immersion process forms a SAM layer 216 on the metal material 210 as depicted in a view 200B of FIG. 2. The carbon in the SAM layer 216 makes the SAM layer 216 hydrophobic. The SAM layer 216 adsorption only occurs on metallic surfaces of the metal material 210 of the substrate 202. In some embodiments, a thickness 224 of the SAM layer 216 may be from greater than zero nanometers to approximately 10 nanometers. The SAM layer 216 functions as a barrier to oxygen to keep the metal material 210 from oxidizing during the wafer-level processing. By keeping the surface of the metal material 210 clean, subsequent annealing processes to diffuse the metal material 210 into an interconnect after bonding may be performed at a substantially lower temperature (e.g., approximately 150 degrees Celsius) than if the surface has oxidation. The SAM layer 216 also functions as a hydrophobic layer that enables subsequent selective dielectric deposition. After the SAM layer 216 has been formed, the SAM layer 216 may remain stable on the metal material surfaces for up to approximately 24 hours, allowing for a delay in bonding if a bonding process requires a delay and/or if pre-processing is needed to increase bonding throughput. The duration of the SAM layer viability can be adjusted by adjusting the length of, for example, the alkanethiol chain, with longer chains providing longer viability of the SAM layer 216. In some embodiments, the substrate is rinsed with deionized water after the immersion process is completed.

In block 106, after formation of the SAM layer 216, a high-k dielectric material capping layer 218 is selectively deposited on the dielectric material 206 of the substrate 202 as depicted in a view 200C of FIG. 2. As used herein, ‘high-k dielectric material’ refers to dielectric materials with a dielectric constant (k-value) of greater than 3.9. In some instances, the high-k dielectric material capping layer 218 may also be deposited on exposed portions 220 of the barrier/liner layer 208 at the surface of the substrate 202. In some embodiments, a thickness 226 of the high-k dielectric material capping layer 218 may be from greater than zero nanometers to approximately 10 nanometers. Thinner layers of the high-k dielectric are preferred so as to not unduly increase the distance (dishing space 306 of view 300B of FIG. 3, dishing space 306 should be 5 nm or less) between the metal material 210 which could impede diffusion during annealing/bonding of the metal materials. The selective deposition process of the high-k dielectric material is enabled by the hydrophobic qualities of the SAM layer 216. The high-k dielectric material may be deposited using a precursor in an ALD process that prefers to form on hydrophilic surfaces such as the surfaces of the dielectric material 206 of the substrate 202 rather than on the hydrophobic surface of the SAM layer 216. In some embodiments, processes other than ALD processes may be used to deposit the high-k dielectric material. In some embodiments, the high-k dielectric material may be aluminum oxide, hafnium oxide, or titanium oxide and the like.

In block 108, after selective deposition of the high-k dielectric material, the SAM layer 216 is removed from the substrate 202 as depicted in a view 200D of FIG. 2. In some embodiments, the removal of the SAM layer 216 may be performed after a substrate has undergone dicing or singulation to separate the substrate into individual dies. The SAM layer 216 desorption may be accomplished by thermal or mechanical processes. In some embodiments, a plasma process is used to remove the SAM layer 216 and expose the metal material 210 on the surface of the substrate 202. The plasma process may have a duration of approximately 10 seconds to approximately 60 seconds to remove the SAM layer 216. If an alkanethiol with a benzene ring structure has been used for the SAM layer 216, the plasma process may have a duration of several minutes to remove the larger molecules. The plasma process also functions to activate the surface of the high-k dielectric material capping layer 218 prior to bonding. Once the SAM layer 216 has been removed, the substrate 202 is ready for bonding. In some embodiments, only one of the two substrates to be bonded together may have the high-k dielectric material capping layer 218. For the sake of brevity, the following examples are depicted with both of the substrates to be bonded together having the high-k dielectric material capping layer 218.

In block 110, the high-k dielectric material capping layer 218A of the substrate 202A is bonded to the high-k dielectric material capping layer 218B of the substrate 202B as depicted in views 300A and 300B of FIG. 3. The bonding between the high-k dielectric material capping layer 218A and the high-k dielectric material capping layer 218B occurs when the two layers comes into contact. No additional external force is required to be applied to the substrates to accomplish the high strength bond between the high-k dielectric materials. Due to the dishing of the metal material 210A of the substrate 202A and the metal material 210B of the substrate 202B, the metal materials do not come into contact with each other during the bonding of the high-k dielectric materials as depicted in the view 300B of FIG. 3. The bonded substrate 302 depicted in view 300B may be, as discussed prior, two substrates, a die and a substrate, or even two dies bonded together and the like.

In block 112, the bonded substrate 302 undergoes an annealing process to expand and diffuse the metal material 210A and the metal material 210B to form an interconnect 304 as depicted in a view 300C of FIG. 3. Due to the SAM layer 216 acting as an oxygen barrier (passivation layer) to the metal material 210, the metal material 210 is kept from oxidizing and thus can be readily diffused at lower temperatures such as approximately 150 degrees Celsius and still yield an interconnect with high performance characteristics (e.g., low resistance/high conductance, void-free, etc.). For example, with a metal material 210 such as copper, the copper-to-copper bonding strength using the SAM layer 216 may have a five-to-six-fold increase in shear strength over bonding processes without the SAM layer 216. The dielectric bonding strength after annealing is greater at all annealing temperatures with the high-k dielectric material capping layer 218 than processes without the high-k dielectric material capping layer 218. The dielectric bonding strength more than doubles as the annealing temperatures reach approximately 300 degrees Celsius or greater. Substrates undergoing the above methods of the present principles will have higher bonding strengths for both dielectric materials and metal materials for any given thermal budget.

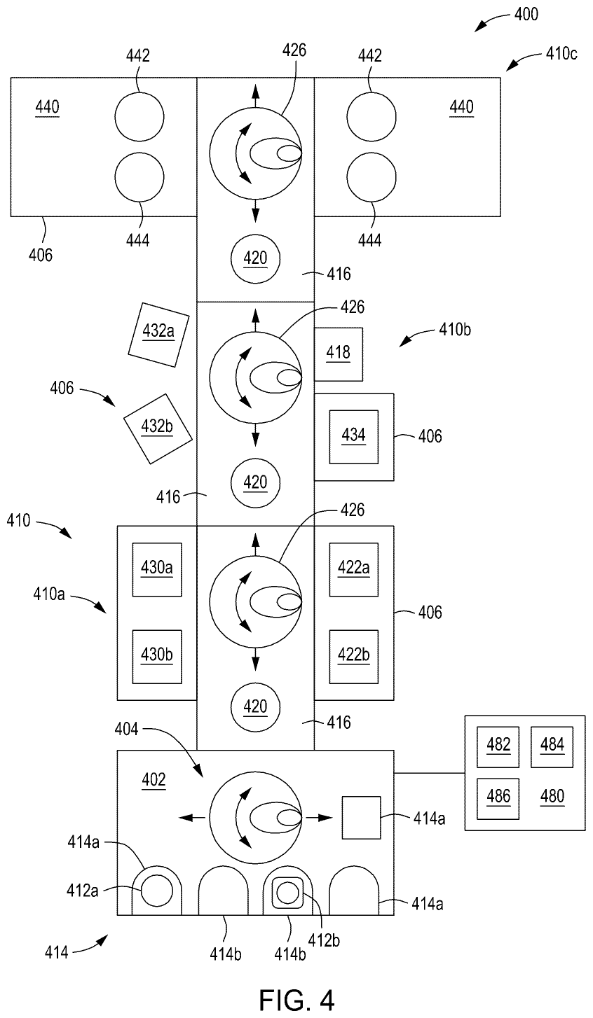

The dielectric bonding strengthening techniques of the present principles may be performed independently or incorporated into integrated hybrid bonding processes and tools. For example, in FIG. 4, a schematic top view of an integrated hybrid bonding tool 400 for bonding dies to a substrate is depicted in accordance with some embodiments. The integrated hybrid bonding tool 400 generally includes an equipment front end module (EFEM) 402 and a plurality of automation modules 410 that are serially coupled to the EFEM 402. The plurality of automation modules 410 are configured to shuttle one or more types of substrates 412 from the EFEM 402 through the integrated hybrid bonding tool 400 and perform one or more processing steps to the one or more types of substrates 412. Each of the plurality of automation modules 410 generally include a transfer chamber 416 and one or more process chambers 406 coupled to the transfer chamber 416 to perform the one or more processes such as immersion for SAM layer formation and selective dielectric material deposition. The plurality of automation modules 410 are coupled to each other via their respective transfer chamber 416 to provide modular expandability and customization of the integrated hybrid bonding tool 400. As depicted in FIG. 4, the plurality of automation modules 410 comprise three automation modules, where a first automation module 410a is coupled to the EFEM 402, a second automation module 410b is coupled to the first automation module 410a, and a third automation module 410c is coupled to the second automation module 410b.

The EFEM 402 includes a plurality of load ports 414 for receiving one or more types of substrates 412. In some embodiments, the plurality of load ports 414 include at least one of one or more first load ports 414a for receiving a first type of substrate 412a or one or more second load ports 414b for receiving a second type of substrate 412b. The integrated hybrid bonding tool 400 may also incorporate a buffer 490 that provides temporary storage or buffering for sources and targets alike. In some embodiments, the EFEM 402 includes a scanning station 408 having substrate ID readers for scanning the one or more types of substrates 412 for identifying information. An EFEM robot 404 is disposed in the EFEM 402 and configured to transport the first type of substrates 412a and the second type of substrates 412b between the plurality of load ports 414 to the scanning station 408. The EFEM robot 404 may include substrate end effectors for handling the first type of substrates 412a and second end effectors for handling the second type of substrates 412b. The EFEM robot 404 may rotate or rotate and move linearly.

The transfer chamber 416 includes a buffer 420 configured to hold one or more first type of substrates 412a. The transfer chamber 416 includes a transfer robot 426 configured to transfer the first type of substrates 412a and the second type of substrates 412b between the buffer 420, the one or more process chambers 406, and a buffer disposed in an adjacent automation module of the plurality of automation modules 410. The one or more process chambers 406 may include atmospheric chambers that are configured to operate under atmospheric pressure and vacuum chambers that are configured to operate under vacuum pressure. Examples of the atmospheric chambers may generally include SAM immersion tanks, wet clean chambers, plasma chambers, radiation chambers, heating chambers, metrology chambers, bonding chambers, or the like. Examples of vacuum chambers may include plasma chambers, selective dielectric material deposition chambers, and the like.

The wet clean chamber 422 is configured to perform a wet clean process to clean the one or more types of substrates 412 via a fluid, such as water. The wet clean chamber 422 may include a first wet clean chamber 422a for cleaning the first type of substrates 412a or a second wet clean chamber 422b for cleaning the second type of substrates 412b. The degas chamber 432 is configured to perform a degas process to remove moisture via, for example, a high temperature baking process. In some embodiments, the degas chamber 432 includes a first degas chamber 432a and a second degas chamber 432b. The plasma chamber 430 may be configured to perform an activation and/or cleaning process on a substrate in preparation for hybrid bonding. The activation aids in increasing bonding strength between surfaces. In some embodiments, the plasma chamber 430 includes a first plasma chamber 430a and a second plasma chamber 430b. The radiation chamber 434 is configured to perform a radiation process to reduce adhesion between dies on a source such as, for example, a tape frame substrate or a carrier substrate with reconstituted dies. The bonder chamber 440 is configured to transfer and bond at least a portion of the dies from a source to a target substrate. The bonder chamber 440 generally includes a first support 442 to support one of the first type of substrates 412a and a second support 444 to support one of the second type of substrates 412b.

In some embodiments, a last automation module of the plurality of automation module 410, for example the third automation module 410c of FIG. 4, includes one or more bonder chambers 440 (two shown in FIG. 4). In some embodiments, a first of the two bonder chambers is configured to remove and bond active dies and a second of the two bonder chambers is configured to remove and bond dummy dies. In some embodiments, any of the plurality of automation modules 410 include a metrology chamber 418 configured to take measurements of the one or more types of substrates. In FIG. 4, the metrology chamber 418 is shown as a part of the second automation module 410b coupled to the transfer chamber 416 of the second automation module 410b. However, the metrology chamber 418 may be coupled to any transfer chamber 416 or within the transfer chamber 416.

A controller 480 controls the operation of any of the integrated hybrid bonding tools described herein, including the integrated hybrid bonding tool 400. The controller 480 may use a direct control of the integrated hybrid bonding tool 400, or alternatively, by controlling the computers (or controllers) associated with the integrated hybrid bonding tool 400. In operation, the controller 480 enables data collection and feedback from the integrated hybrid bonding tool 400 to optimize performance of the integrated hybrid bonding tool 400 and to control the processing flow according to methods described herein. The controller 480 generally includes a central processing unit (CPU) 482, a memory 484, and a support circuit 486. The CPU 482 may be any form of a general-purpose computer processor that can be used in an industrial setting. The support circuit 486 is conventionally coupled to the CPU 482 and may comprise a cache, clock circuits, input/output subsystems, power supplies, and the like. Software routines, such as methods as described herein may be stored in the memory 484 and, when executed by the CPU 482, transform the CPU 482 into a specific purpose computer (controller 480). The software routines may also be stored and/or executed by a second controller (not shown) that is located remotely from the integrated hybrid bonding tool 400.

The memory 484 is in the form of computer-readable storage media that contains instructions, when executed by the CPU 482, to facilitate the operation of the semiconductor processes and equipment. The instructions in the memory 484 are in the form of a program product such as a program that implements methods of the present principles. The program code may conform to any one of a number of different programming languages. In one example, the disclosure may be implemented as a program product stored on a computer-readable storage media for use with a computer system. The program(s) of the program product define functions of the aspects (including the methods described herein). Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored; and writable storage media (e.g., floppy disks within a diskette drive or hard-disk drive or any type of solid-state random access semiconductor memory) on which alterable information is stored. Such computer-readable storage media, when carrying computer-readable instructions that direct the functions of the methods described herein, are aspects of the present principles.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method for increasing dielectric bonding strength during wafer-level processing, comprising:
immersing a substrate into a chemical bath, wherein the chemical bath forms a self-assembled monolayer on at least one metal surface of the substrate; and
selectively depositing a dielectric material to form a dielectric cap on at least one dielectric surface of the substrate absent of the self-assembled monolayer.

2. The method of claim 1, wherein immersing the substrate into the chemical bath occurs at atmospheric pressure and ambient temperature.

3. The method of claim 1, further comprising:
removing the self-assembled monolayer from the substrate;
bonding the dielectric material of the substrate to another substrate with surfaces covered by the dielectric material by contacting substrates together; and
annealing substrates to bond metal surfaces together.

4. The method of claim 3, further comprising:
removing the self-assembled monolayer using a plasma-based process for approximately 10 seconds to approximately 60 seconds.

5. The method of claim 3, wherein the substrate is a die.

6. The method of claim 3, wherein annealing occurs at a temperature of approximately 150 degrees Celsius.

7. The method of claim 1, wherein the chemical bath includes an alkanethiol.

8. The method of claim 7, wherein the alkanethiol has a linear structure or a benzene ring structure.

9. The method of claim 1, wherein the dielectric material is a high-k dielectric material.

10. The method of claim 9, wherein the high-k dielectric material is aluminum oxide or hafnium oxide.

11. The method of claim 1, wherein the substrate is immersed in the chemical bath for approximately 10 minutes to approximately 30 minutes.

12. The method of claim 1, wherein the metal surface is copper, silver, gold, palladium, platinum, cobalt, titanium, nickel, or combinations thereof.

13. The method of claim 1, wherein a thickness of the dielectric material is greater than zero nm to approximately 10 nm.

14. A method for increasing dielectric bonding strength during wafer-level processing, comprising:
immersing a substrate into a chemical bath, wherein the chemical bath forms a self-assembled monolayer on at least one metal surface of the substrate and wherein immersing the substrate into the chemical bath occurs at atmospheric pressure and ambient temperature; and
selectively depositing a high-k dielectric material to form a dielectric cap on at least one dielectric surface of the substrate absent of the self-assembled monolayer, wherein a thickness of the high-k dielectric material is greater than zero nm to approximately 10 nm.

15. The method of claim 14, wherein the substrate is immersed in the chemical bath for approximately 10 minutes to approximately 30 minutes.

16. The method of claim 14, further comprising:
removing the self-assembled monolayer from the substrate;
bonding the high-k dielectric material of the substrate to another substrate with surfaces covered by the high-k dielectric material by contacting substrates together; and
annealing substrates to bond metal surfaces together.

17. The method of claim 16, further comprising:
removing the self-assembled monolayer using a plasma-based process for approximately 10 seconds to approximately 60 seconds.

18. The method of claim 14, wherein the chemical bath includes an alkanethiol with a linear structure or a benzene ring structure.

19. The method of claim 14, wherein the high-k dielectric material is aluminum oxide or hafnium oxide.

20. A non-transitory, computer readable medium having instructions stored thereon that, when executed, cause a method for increasing dielectric bonding strength during wafer-level processing to be performed, the method comprising:
immersing a substrate into a chemical bath, wherein the chemical bath forms a self-assembled monolayer on at least one metal surface of the substrate and wherein immersing the substrate into the chemical bath occurs at atmospheric pressure and ambient temperature; and
selectively depositing a dielectric material to form a dielectric cap on at least one dielectric surface of the substrate absent of the self-assembled monolayer.
